(19) United States
(12) Patent Application Publication
(10) Pub. No.: US 2025/0138100 A1
(43) Pub. Date: May 1, 2025

(54) BATTERY CELL CLASSIFICATION SYSTEM AND METHOD

(71) Applicants: Hyundai Motor Company, Seoul (KR); Kia Corporation, Seoul (KR); Seoul National University R&DB Foundation, Seoul (KR)

(72) Inventors: Junhee Lee, Bucheon-si (KR); Chun Yong Kang, Yongin-si (KR); Kimoon Um, Suwon-si (KR); Jang Wook Choi, Seoul (KR); Min Soo Kim, Seoul (KR); In Woo Kim, Seoul (KR); Hyun Jae Kim, Seoul (KR)

(21) Appl. No.: 18/584,198

(22) Filed: Feb. 22, 2024

(30) Foreign Application Priority Data
Oct. 26, 2023 (KR) 10-2023-0144736

(51) Int. Cl. G01R 31/385; G01R 31/367; G01R 31/388; G01R 31/396

(52) U.S. Cl. CPC G01R 31/3865; G01R 31/388; G01R 31/396; G01R 31/367

(57) ABSTRACT

A battery cell classification system may include a charging voltage differential value measurement device configured to determine a charging voltage differential value of a battery cell before assembling a battery module, a uniformity factor extractor configured to extract a uniformity factor based on determining uniformity of the battery cell among determined charging voltage differential values, and a controller configured to compare a uniformity factor of the battery cell with a reference uniformity value, so as to reject the battery cell as a defective cell if it has the uniformity value smaller than the reference uniformity value, or to classify battery cell based on uniformity factor if it has the uniformity value at or above than the reference uniformity value.

### CROSS-REFERENCE TO RELATED APPLICATIONS

This application claims the benefit of Korean Patent Application No. 10-2023-0144736, filed on Oct. 26, 2023, which application is hereby incorporated herein by reference.

### TECHNICAL FIELD

The present disclosure relates to a battery cell classification system and method.

### BACKGROUND

Recently, to reduce carbon emissions, the spread of motorized electric vehicles (EVx), including various hybrid electric vehicles (HEV), has been rapidly increasing as a replacement for internal combustion engine vehicles. The batteries used in these electric vehicles are lithium-ion secondary batteries that exhibit excellent performance in terms of energy density and output.

These secondary batteries are manufactured by assembling a plurality of battery cells to form a battery module, and then assembling the plurality of battery modules to finally form a battery pack that may be mounted on an electric vehicle. At this time, the performance of the battery module and battery pack tends to be determined by the battery cell with the lowest performance among the included battery cells. Because of this, even if most battery cells have excellent performance, if one battery cell is defective or a deviation occurs that reduces performance, there is a problem that the performance of the battery module and battery pack deteriorates.

Meanwhile, in relation to the above, in the related art, there is a technology for classifying battery cells based on their capacity or voltage, but because the battery cell capacity and voltage do not have a clear relationship with the performance of the battery, there is a disadvantage in that classification according to performance is not possible. In addition, because the rate at which battery cells deteriorate by operation may vary depending on manufacturing variations, it is difficult to believe that it has the effect of reducing the variation of cells forming modules and packs.

Therefore, to ensure stable performance of battery modules and battery packs, it is important to detect defective battery cells before assembling modules and packs and classify battery cells with similar performance to reduce driving deviation of the assembled cells.

The above information disclosed in this Background section is only for enhancement of understanding of the background of the disclosure, and therefore it may contain information that does not form the prior art that is already available to the public.

### SUMMARY

The present disclosure relates to a battery cell classification system and method. More particularly, the present disclosure relates to a battery cell classification system and method capable of classifying a defective cell and cells of similar uniformities through battery cell uniformity diagnosis.

An embodiment of the present disclosure can provide a battery cell classification system and method capable of extracting a peak value at a charging voltage differential curve derived when charging assembled battery cells as a uniformity factor, detecting a defective cell of which the uniformity factor is less than a reference uniformity value, and/or classifying battery cells having similar uniformity factors.

A battery cell classification system may include a charging voltage differential value calculator configured to calculate a charging voltage differential value of the battery cell before assembling a battery module, a uniformity factor extractor configured to extract a factor for determining uniformity of the battery cell (hereinafter, referred to as a uniformity factor) among calculated charging voltage differential values, and a controller configured to compare a uniformity factor of the battery cell with a selected, set, preset, or predetermined reference uniformity value, so as to discharge the battery cell having the uniformity value smaller than the reference uniformity value as a defective cell or to classify battery cells having similar uniformity factors.

A battery cell classification system may further include a battery charging and discharging unit configured to connect and initially charge both side electrodes of an assembled plurality of battery cells at selected, set, preset, or predetermined current, and a storage unit configured to store program and data for operating the battery cell classification system.

The charging voltage differential value calculator may be configured to extract a charging voltage and a charging current according to time series when charging the battery cell.

The charging voltage differential value calculator may be configured to derive a charging voltage curve based on a charging voltage and a charging current measured in time series when charging the battery cell, and to calculate a time series charging voltage differential curve by first order differentiating the charging voltage curve.

The uniformity factor extractor may be configured to extract a peak value around a state of charge (SOC) of 60% among the charging voltage differential curve as the uniformity factor.

The controller may be configured to set the reference uniformity value required or set for the battery cell classification and the defective cell based on a normal distribution accumulating a selected, set, preset, or predetermined amount of the uniformity factor of the battery cell.

The controller may be configured to set a lower 5% value of the uniformity factor of the normal distribution as the reference uniformity value for determining the defective cell.

The controller may be configured to set a value lower than from an average value of a plurality of reference uniformity values that is accumulated from the past by a particular deviation as the reference uniformity value for determining the defective cell.

The controller may be configured to determine the uniformity factor above a reference uniform value as a normal battery cell, and to classify cells determined as the normal battery cell in a descending order according to the uniformity factor value.

The controller may be configured to group the battery cells having similar uniformity factors and input them into a battery module assembly process.

A battery cell classification method of a battery cell classification system may include initially charging the assembled battery cell and calculating a charging voltage differential curve during charging, extracting a peak value around a SOC of 60% among the charging voltage differential curve as a uniformity factor, determining whether a uniformity factor of the battery cell is above a reference uniformity value, and when the uniformity factor is not above the reference uniformity value, determining the battery cell as a defective battery cell and discharge the battery cell, and determining the battery cell as a normal battery cell when the uniformity factor is above the reference uniformity value, and classifying normal battery cells into battery cells having similar uniformity factors.

A battery cell classification method may further include, when a quantity of uniformity factors accumulated from the battery cells of a same model satisfies a selected, set, preset, or predetermined amount, generating a normal distribution, and setting the reference uniformity value based on the normal distribution.

The selected, set, preset, or predetermined amount may be set as a quantity of the uniformity factors of battery cells included in one lot or a quantity of the uniformity factors satisfying a normal distribution generation condition.

The calculating of the charging voltage differential curve may include deriving a charging voltage curve by using a charging voltage and a charging current measured in time series during charging, and calculating the charging voltage differential curve by first order differentiating the charging voltage curve.

The classifying the battery cells may include classifying the uniformity factor in a descending order, grouping them according to the number of battery modules, and inputting the group into a battery module assembly process.

According to an embodiment of the present disclosure, by detecting defective cells and classifying battery cells having similar uniformities by using uniformity factor capable of diagnosing interior uniformity of battery cells, driving deviation of cells included in the assembled battery module and the battery pack may be reduced.

In addition, uniformity factor can be a non-destructive electrochemical signal that may be obtained as a differential value of a charging voltage, and because the uniformity factor of the battery cell measured in the first cycle has a linear relationship with the lifespan of the cell, the expected lifespan of the cell may be predicted.

In addition, because the battery module and battery pack may be manufactured with cells classified as having similar uniformity factors, deterioration of lifespans of configured cells may be prevented, and the overall battery performance may be improved by minimizing performance deviation between cells.

### BRIEF DESCRIPTION OF THE DRAWINGS

The above and other features and advantages of the present disclosure can be more apparent from the following detailed description taken in conjunction with the accompanying drawings, in which:

FIG. 1 is a block diagram schematically showing a configuration of a battery cell classification system according to an embodiment of the present disclosure;

FIG. 2 is a graph showing a charging voltage curve and a charging voltage differential curve according to an embodiment of the present disclosure;

FIG. 3 to FIG. 5C are graphs, images, and drawings for explaining a reason why a uniformity factor of a battery cell is extracted according to an embodiment of the present disclosure;

FIG. 6 are graphs for explaining the reason why detection of defective cells or classification according to performance is possible based on a uniformity factor according to an embodiment of the present disclosure;

FIG. 7 is a graph illustrating an example of defecting cell detection and/or setting a reference uniformity factor for cell classification according to an embodiment of the present disclosure;

FIG. 8 is a flowchart showing a battery cell classification method of a battery cell classification system according to an embodiment of the present disclosure;

FIGS. 9A and 9B are graphs and drawings showing an experimental result of performance when the module is assembled with cells classified according to a uniformity factor according to an embodiment of the present disclosure; and

FIGS. 10A and 10B are graphs showing an experimental result of performance when the battery module is assembled by performing classification for the uniformity deviation between battery cells to be small according to an embodiment of the present disclosure.

### DETAILED DESCRIPTION OF ILLUSTRATIVE EMBODIMENTS

Embodiments of the present disclosure will be described more fully hereinafter with reference to the accompanying drawings, in which example embodiments of the disclosure are shown.

The terminology used herein is for the purpose of describing particular embodiments and is not intended to be necessarily limiting of the present disclosure. As used herein, the singular forms can include the plural forms as well, unless the context clearly indicates otherwise. It can be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any one or all combinations of one or more related items.

Throughout the specification, terms such as “first”, “second”, “A”, “B”, “(a)”, “(b)”, and the like, can be used to describe various elements, and are not necessarily limiting these elements. Such terms can be merely for distinguishing the constituent elements from other constituent elements, and nature or order of the constituent elements is not necessarily limited by such term.

In this specification, it can be understood that when one component is referred to as being “connected” or “coupled” to another component, it may be connected or coupled directly to the other component or be connected or coupled to the other component with a further component intervening therebetween. In this specification, it can be understood that when one component is referred to as being “connected or coupled directly” to another component, it may be connected to or coupled to the other component without another component intervening therebetween.

Throughout the specification, the terms used herein can be merely used to describe certain embodiments and are not intended to necessarily limit the present disclosure.

Additionally, it can be understood that one or more of the below methods, or aspects thereof, may be executed by at least one controller. The term “controller” may refer to a hardware device that includes a memory and a processor. The memory can be configured to store program instructions, and the processor can be specifically programmed to execute the program instructions to perform one or more processes that are described further below. The controller may control operation of units, modules, parts, devices, or the like, as described herein. Moreover, it can be understood that the below methods may be executed by an apparatus comprising the controller in conjunction with one or more other components, as would be appreciated by a person of ordinary skill in the art.

Hereinafter, a battery cell classification system and method according to an embodiment of the present disclosure will be described in detail with reference to the drawings.

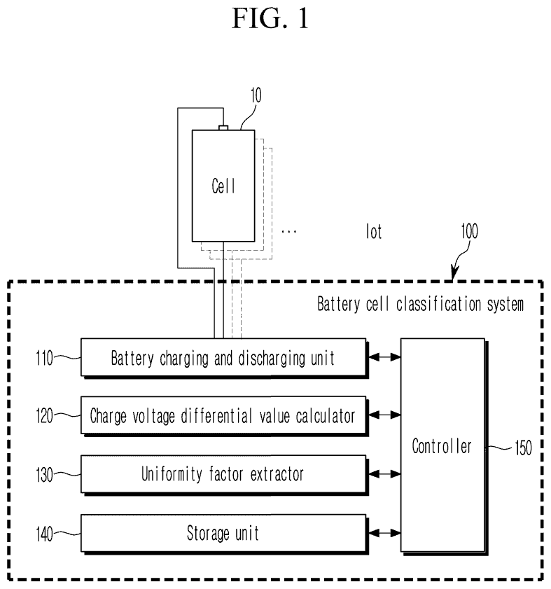

FIG. 1 is a block diagram schematically showing a configuration of a battery cell classification system according to an embodiment of the present disclosure.

Referring to FIG. 1, a battery cell classification system 100 according to an embodiment may include a charging voltage differential value calculator 120 configured to calculate a charging voltage differential value of a battery cell 10 before assembling a battery module, a uniformity factor extractor 130 configured to extract a factor for determining uniformity of the battery cell 10 (hereinafter, referred to as a uniformity factor) among calculated charging voltage differential values, and a controller 150 configured to compare the uniformity factor of the battery cell 10 with a threshold, selected, set, preset, or predetermined reference uniformity value, so as to discharge the battery cell 10 having the uniformity value smaller than the reference uniformity value as a defective cell or to classify battery cells having similar uniformity factors.

A battery charging and discharging unit 110 configured to connect and initially charge both side electrodes of an assembled plurality of battery cells 10 at a threshold, selected, set, preset, or predetermined current, and a storage unit 140 configured to store at least one program and data for an operation of the battery cell classification system 100 and store data generated according to the operation may be further included.

The battery cell classification system 100 may be located in an inspection/classification process between a battery module assembly process and a battery cell assembly process of a battery manufacturing factory, for example. In the battery cell assembly process, the battery cell classification system 100 may not only determine whether the assembled battery cell 10 is defective (OK or not good, NG) but may also group the battery cells 10 having similar uniformity factors grouping, and input them into the battery module assembly process. Therefore, performance deviation between the battery cells 10 included in the assembled battery module may be reduced, and furthermore, performance deviation between battery modules included in a battery pack may be minimized.

The battery cell 10, which can be a lithium ion secondary battery, may be cylindrical, prismatic, pouch-shaped, and for convenience, cylindrical cells are illustrated in the description below as an example. In addition, when describing a battery/secondary battery, the battery cell 10, the battery module, and the battery pack may sometimes be abbreviated as “cell,” “module,” and “pack.”

Hereinafter, in connection with the battery cell 10 according to an embodiment of the present disclosure, a method for extracting the uniformity factor, classification reference, and a method of classification will be described in further detail.

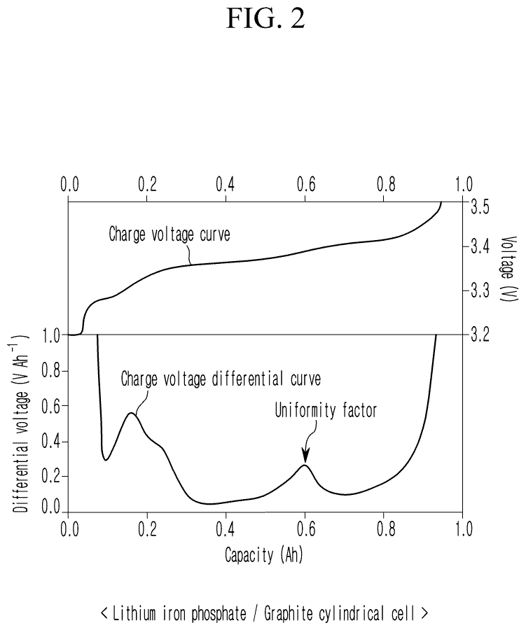

FIG. 2 is a graph showing a charging voltage curve and a charging voltage differential curve according to an embodiment of the present disclosure.

Referring to FIG. 2, the charging voltage differential value calculator 120 may extract charging voltage charging current according to time series when charging the battery cell 10.

The charging voltage differential value calculator 120 may derive the charging voltage curve based on a charging voltage and a charging current measured in time series during charging, and may calculate a time series charging voltage differential curve by first order differentiating the charging voltage curve. In the charging voltage curve, the x-axis represents capacity and y-axis represents voltage, and in the charging voltage differential curve, the x-axis represents capacity and y-axis represents a differential voltage with respect to capacity.

The uniformity factor extractor 130 may extract a peak value around an SOC of 60% among the charging voltage differential curve as the uniformity factor, and store it in the storage unit 140.

The controller 150 may control an overall operation for operating the battery cell classification system 100, and may set the reference uniformity value required or set for the battery cell classification and the defective cell based on a normal distribution accumulating a threshold, selected, set, preset, or predetermined amount of the uniformity factors of the battery cells 10.

For example, the controller 150 may set a lower 5% value of the uniformity factor of the normal distribution as the reference uniformity value for determining the defective cell. However, an embodiment is not necessarily limited thereto, and the controller 150 may set a value lower from an average value of a plurality of reference uniformity values that is accumulated from the past by a particular deviation as the reference uniformity value for determining the defective cell.

During the battery cell classification operation, the controller 150 may determine the battery cell 10 having a smaller uniformity factor than the reference uniform value as the defective cell, and discharge it.

In addition, during the battery cell classification, the controller 150 may determine the uniformity factor above the reference uniform value as a normal battery cell 10, and classify cells determined as the normal battery cell 10 in a descending order according to the uniformity factor value. Therefore, the battery module may be assembled to be composed of battery cells having similar level of the uniformity factor without manufacture deviation and performance deviation on a cell-by-cell basis, and furthermore, a battery pack without a performance deviation may be manufactured.

The uniformity factor can be used in the diagnosis of defectiveness, performance, and lifespan of individual battery cells according to an embodiment, and cell classification characteristics according thereto will be described in detail with reference to the drawings.

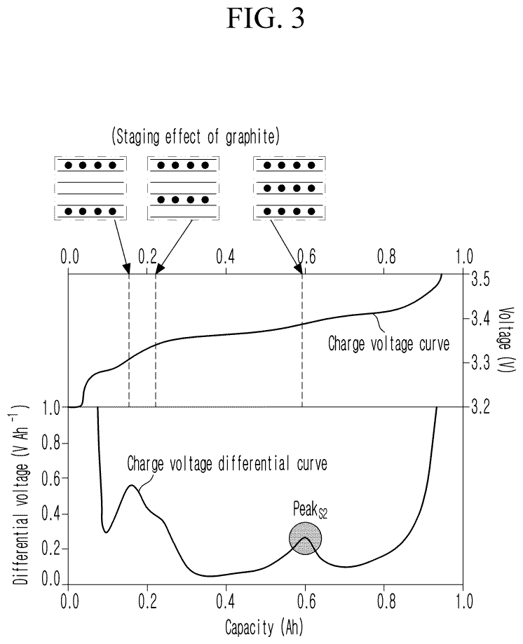

FIG. 3 to FIG. 5C are graphs, images, and drawings for explaining a reason why a uniformity factor of a battery cell is extracted according to an embodiment of the present disclosure.

First, referring to FIG. 3, during charging of the battery cell 10, a staging effect can occur in which lithium ions are inserted layer by layer at intervals into the graphite negative electrode.

The voltage can change significantly at the point where each stage is completely formed, the slope of the charging voltage curve can become steeper, and it can appear as a peak in the charging voltage differential curve.

The uniformity factor according to an embodiment extractor 130 may select a peak value Peak_{S2} around an SOC of 60% among the charging voltage differential curve as the uniformity factor. The reason for selecting the stage around an SOC of 60% among the three stages is because the peak Peak_{S2} around an SOC of 60% experimentally can have the highest correlation with cell state (performance).

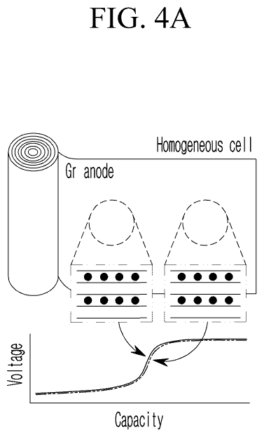

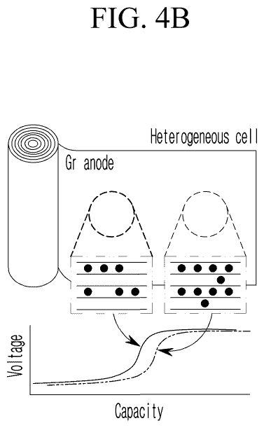

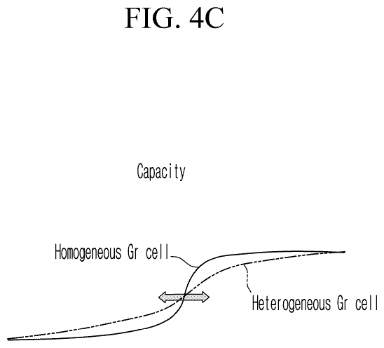

Subsequently, in the case of a homogeneous cell as shown in FIG. 4(A), the degree of lithium insertion is the same for each position of the graphite negative electrode. But in the case of a heterogeneous cell as shown in FIG. 4(B), the degree of lithium insertion may vary depending on position of the graphite negative electrode. Because the graphite negative electrode develops different voltages depending on the location and the voltage of the battery cell appears as a single voltage by combining the voltages across the electrode plates, in the case of non-uniform battery cells, the slope of the charging voltage curve can become gentler and the peak of the charging voltage differential curve can be lowered.

Therefore, as shown in FIG. 4(C), as the battery cells are more non-uniform, the peak value in the charging voltage differential curve is lower, and conversely, as the battery cells are more uniform the battery cells, the peak value in the charging voltage differential curve is higher.

Accordingly, the battery cell classification system 100 according to an embodiment may extract the peak Peak_{S2} value of the charging voltage differential curve derived when charging the battery cell 10 as the uniformity factor, and detect the defective cell based on the uniformity factor or classify the battery cells having similar uniformity factors.

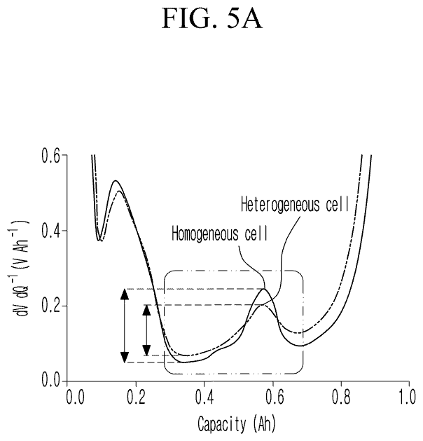

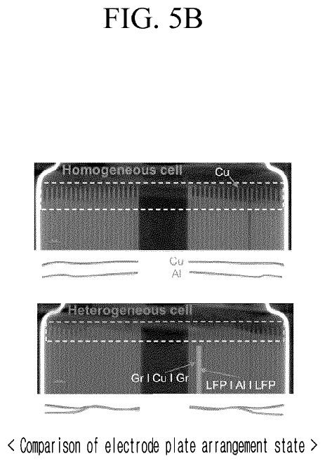

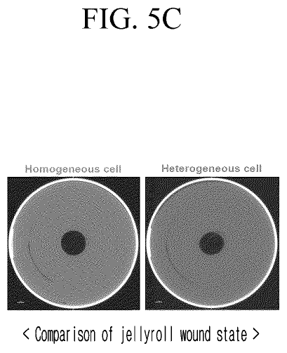

Subsequently, referring to FIGS. 5A-5C, experimental results showing that the uniformity factor described above can be actually related to the interior of the battery cell 10 are shown.

In FIG. 5(A), a charging differential voltage curve can be derived through one initial charge of a plurality of battery cells (e.g., cells of one lot) with no charging history after assembly, and among them, two cells with the largest deviation in uniformity factor are shown. Among the two cells, one with a larger uniformity factor corresponding to the peak value around an SOC of 60% is defined as a homogeneous cell, and one with a smaller uniformity factor is defined as a heterogeneous cell.

FIG. 5(B) and FIG. 5(C) shows comparisons of CT scan result of interiors of the homogeneous cell and the heterogeneous cell.

Referring to FIG. 5(B), when the arrangement of electrode plates is compared, it appears that the electrode plate arrangement of the homogeneous cell is more uniform. In addition, referring to FIG. 5(C), when the jelly roll wound state within the cell is compared, the jelly roll wound state of the homogeneous cell appears to be better.

Therefore, it may be confirmed that the uniformity factor extracted in an embodiment can be actually related to the uniformity of the battery cell 10.

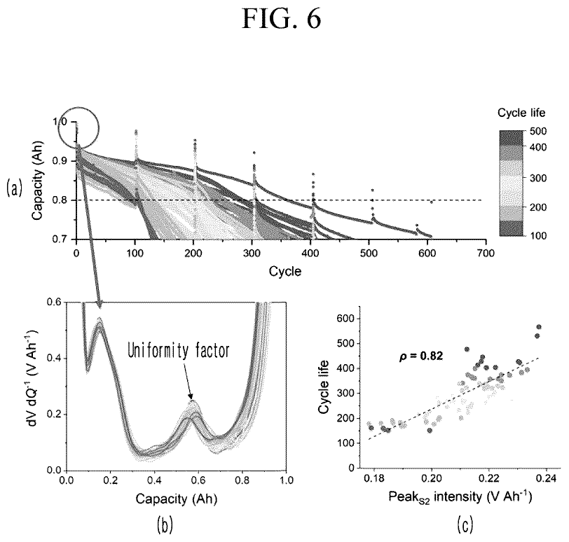

FIG. 6 shows graphs for explaining the reason why detection of defective cells or classification according to performance is possible based on the uniformity factor according to an embodiment of the present disclosure.

Referring to graph (a) of FIG. 6, when the lifespan experiment is performed on 77 LFP/Gr battery cells at the same condition, it may be confirmed that different cycle life are shown according to battery cell manufactured state even in the same condition.

Referring to graph (b) of FIG. 6, when initially charging the battery cells before the lifespan experiment, a state that the peak value of around an SOC of 60% in the charging differential voltage curve derived by differentiating the charging voltage curve is extracted as the uniformity factor is shown.

Referring to graph (c) of FIG. 6, when defining the standard cycle life as the number of cycles until the capacity reaches 80% in the cycle life graph (a) of FIG. 6, it may be seen that the correlation is high because the higher the uniformity factor (Peak_{S2} intensity), the cycle life is longer. Cycle life performance may be predicted by matching the cycle life of the battery cell with the uniformity factor extracted from the differential voltage curve in the battery cell's first charging cycle.

Therefore, because the state of the battery cell may be diagnosed through the uniformity factor extracted immediately after manufacturing the battery cell or before assembling the battery module (before the cycle), it is possible to detect defective cells and/or classify cells according to performance.

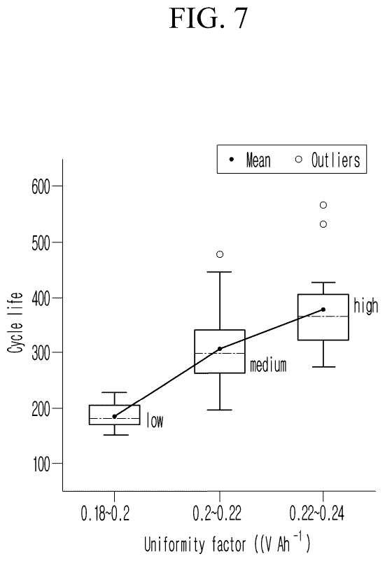

FIG. 7 is a graph that shows an example of defecting cell detection and/or setting a reference the uniformity factor for cell classification according to an embodiment of the present disclosure.

Referring to FIG. 7, according to an embodiment, with respect to 77 cells (e.g., cells of one lot or sufficient number of cells to draw the normal distribution), the uniformity factor may be divided into three groups of low, medium, high. For example, values with a uniformity factor lower than 0.2 have significantly low cycle life, so the defective cell detection reference may be set to 0.2.

Because the uniformity factor can be measured differently depending on cell types, a process of checking the average value and deviation value of accumulating the uniformity factor measured with respect to the threshold, selected, set, preset, or predetermined amounts of cells (one lot or sufficient number to form the normal distribution) of the same model and selecting the defective cell reference value can be preferred.

Accordingly, as described above, the controller 150 may set the reference uniformity value required for the battery cell classification and the defective cell based on the normal distribution accumulating the threshold, selected, set, preset, or predetermined amount of the uniformity factors of the battery cells 10, and thereby may determine defective cells and classify battery cells having the similar uniformity factor.

The controller 150 may be implemented with one or more processors that operate according to a set program stored in a memory, and the set program may be programmed to perform each step of the battery cell classification method according to an embodiment of the present disclosure.

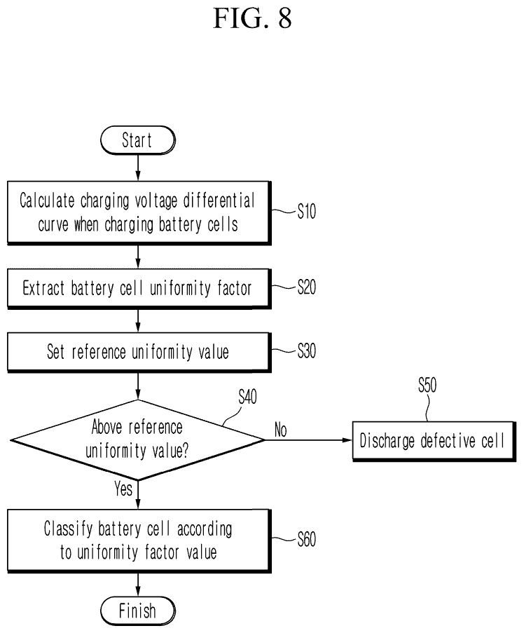

A battery cell classification method according to an embodiment will be described in further detail with reference to FIG. 8.

FIG. 8 is a flowchart showing a battery cell classification method of a battery cell classification system according to an embodiment of the present disclosure.

Referring to FIG. 8, at operation S10, the controller 150 of the battery cell classification system 100 according to an embodiment initially charges the battery cell 10 that is immediately after assembling the battery cell 10 or prior to inputting into a battery module process, and calculates the charging voltage differential curve during charging and stores it.

The controller 150 may derive the charging voltage curve by using a charging voltage and a charging current measured in time series during charging, and calculate the charging voltage differential curve by first order differentiating the charging voltage curve.

At operation S20, the controller 150 may extract a peak value around SOC 60% among the charging voltage differential curve as the uniformity factor and accumulatively store it in the storage unit 140.

At operation S30, when a quantity of uniformity factors accumulated from the battery cells 10 of a same model satisfies the threshold, selected, set, preset, or predetermined amount, the controller 150 may generate the normal distribution, and set the reference uniformity value based on the generated the normal distribution. The threshold, selected, set, preset, or predetermined amount may be the quantity of the uniformity factors of the battery cells 10 included in one lot or a quantity of the uniformity factors satisfying a normal distribution generation condition.

For example, the controller 150 may set the lower 5% value of the uniformity factor of the normal distribution as the reference uniformity value for determining the defective cell. In addition, an embodiment is not limited thereto, and the controller 150 may set a value lower than an average value of a plurality of reference uniformity values that is accumulated from the past by more than the particular deviation as the reference uniformity value for determining the defective cell. The reference uniformity value according to an embodiment is not necessarily a preset value, and may be variably set accordingly to production unit (lot) or manufacture deviation of the battery cells of the factory.

At operation S40, the controller 150 may determine whether the uniformity factor of the battery cell 10 is above the reference uniformity value, and thereby classify the battery cell 10.

At operation S50, when the uniformity factor is not above the reference uniformity value (No at operation S40), the controller 150 may determine that the battery cell 10 is defective and discharge it.

On the other hand, at operation S60, when the uniformity factor is above the reference uniformity value (Yes at operation S40), the controller 150 may determine that the battery cell 10 is normal and may classify the normal battery cells 10 into the battery cells having similar uniformity factors according to the uniformity factor value. The controller 150 may classify the uniformity factor in a descending order, group them according to the number of battery modules, and input them into the battery module assembly process.

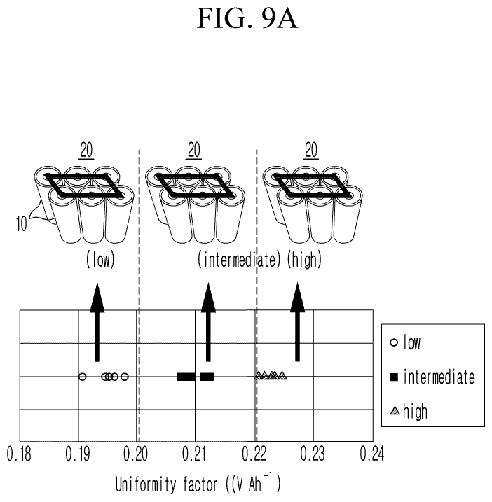

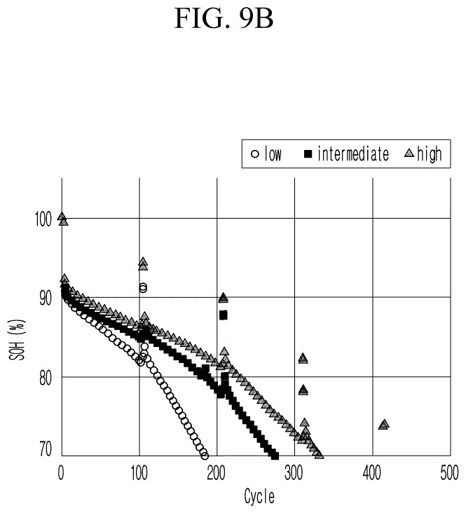

FIGS. 9A and 9B show an experimental result of performance when the module is assembled with cells classified according to the uniformity factor according to an embodiment of the present disclosure.

Referring to FIGS. 9A and 9B, experimental result of the lifespan of the battery module when the battery cells 10 classified into similar level according to the uniformity factor are assembled to a battery module 20 according to above-mentioned battery cell classification method are shown.

For example, when the battery cell 10 is classified, six cells of which the uniformity factor values are lower than 0.2 are classified as a low group, six cells of which the uniformity factor values are 0.2 to 0.22 are classified as an intermediate group, and six cells of which the uniformity factor values are higher than 0.22 are classified as a high group. Then, after forming a high module, an intermediate module, and a low module, the cells were connected in parallel by welding the six cells of each group with a nickel tab, and the cycle life experiment was performed on three modules under the same condition.

As a result of the cycle life experiment, the cycle life of the high module, intermediate module, and low module tends to be longer as the uniformity factor of the configured cells is higher.

Therefore, it may be confirmed that the method of classifying the battery cells based on the uniformity factor by the battery cell classification system 100 according to an embodiment affects module performance when assembling a battery module.

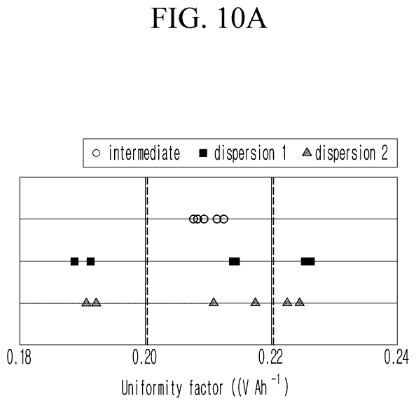

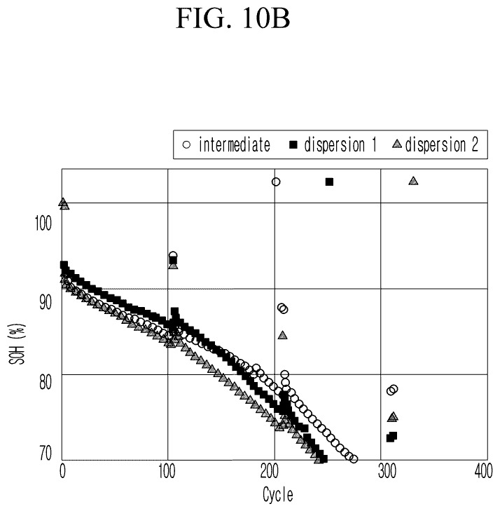

In addition, FIGS. 10A and 10B show an experimental result of performance when the battery module is assembled by performing classification for the uniformity deviation between battery cells to be small according to an embodiment of the present disclosure.

Referring to FIGS. 10A and 10B, the experimental result confirms that assembling the battery module by classify cells such that the performance deviation between cells is small according to an embodiment may improve the performance of the assembled module.

While average value of the uniformity factors of six cells in respective assembled modules is set to be the same (i.e., average value of expected lifespans of six cells of each module is the same), deviation of cell uniformity factor for each module may be configured differently.

For example, they may be classified into the intermediate group of which the uniformity factor deviation between battery cells is small and a group of dispersion 1 and a group of dispersion 2 of which the uniformity factor deviation are relatively large.

In the similar way to FIGS. 9A and 9B, after configuring the intermediate module, a module of dispersion 1, a module of dispersion 2 through welding six cells of each group and then connecting them in parallel, the cycle life experiment was performed on three modules under the same condition.

As a result of the cycle life experiment, even though the three modules have the same expected lifespan average value, the cycle life of the module of dispersion 1 and the module of dispersion 2 of which the uniformity factor deviation are large was low compared to the intermediate module of which the uniformity factor deviation between battery cells is small.

This is because one or two low-performance cells configured in the module causes deterioration of the overall performance of the module, and for example, when one or two cells have short lifespans, they reach the voltage cut-off early when charged, such that the expected capacity of the module may not be implemented. Furthermore, in the case of the battery pack, it is clear that one or two low-performance battery modules have the problem of deteriorating the overall performance of the battery pack.

Therefore, when assembling the battery module, classifying battery cells having similar performance can be very important to improve the overall performance. In addition, as well as improvement on performance side, because voltages of one or two low-lifespan cells are charged earlier, causing the risk of overcharging, improvement of safety may also be expected.

As such, according to an embodiment, by detecting defective cells and classifying battery cells having similar uniformities by using uniformity factor capable of diagnosing interior uniformity of battery cells, driving deviation of cells included in the assembled battery module and the battery pack may be reduced.

In addition, the uniformity factor can be a non-destructive electrochemical signal that may be obtained as a differential value of a charging voltage, and because the uniformity factor of the battery cell measured in the first cycle has a linear relationship with the lifespan of the cell, the expected lifespan of the cell may be predicted.

In addition, because the battery module and the battery pack may be manufactured with cells classified as having similar uniformity factors, deterioration of lifespans of configured cells may be prevented, and the overall battery performance may be improved by minimizing performance deviation between cells.

The example embodiments of the present disclosure described above are not only implemented by the apparatus and the method, but may be implemented by a program for realizing functions corresponding to the configuration of the embodiments of the present disclosure or a recording medium on which the program is recorded.

While this disclosure has been described in connection with what is presently considered to be practical embodiments, it is to be understood that the disclosure is not necessarily limited to the disclosed embodiments. On the contrary, it is intended to cover various modifications and equivalent arrangements included within the spirit and scope of the appended claims.

What is claimed is:

1. A battery cell classification system, comprising:
a charging voltage differential value measurement device configured to determine a charging voltage differential value of the battery cell before assembling a battery module; and
a controller configured to execute code, wherein the code comprises instructions for the controller to
extract a uniformity factor for determining uniformity of the battery cell based on the determined charging voltage differential value,
compare the uniformity factor of the battery cell with a reference uniformity value,
reject the battery cell as a defective cell if the battery cell has the uniformity value smaller than the reference uniformity value, and
classify the battery cell based on the uniformity factor if the battery cell has the uniformity value at or above the reference uniformity value.

2. The system of claim 1, further comprising:
a battery charging and discharging device configured to connect and initially charge both side electrodes of an assembled plurality of battery cells at a set current; and
a storage unit configured to store the instructions and data for operating the battery cell classification system.

3. The system of claim 1, wherein the charging voltage differential value measurement device is configured to extract a charging voltage and a charging current according to time series when charging the battery cell.

4. The system of claim 3, wherein the charging voltage differential value measurement device is configured to derive a charging voltage curve based on the charging voltage and the charging current measured in time series when charging the battery cell, and to determine a time series charging voltage differential curve by first order differentiating the charging voltage curve.

5. The system of claim 4, wherein the code further comprises instructions for the controller to extract a peak value at a state of charge of 60% among the charging voltage differential curve as the uniformity factor.

6. The system of claim 1, wherein the code further comprises instructions for the controller to set the reference uniformity value based on a normal distribution after accumulating a set amount of uniformity factors for a set of battery cells.

7. The system of claim 6, wherein the code further comprises instructions for the controller to set a lower 5% value of the normal distribution as the reference uniformity value.

8. The system of claim 6, wherein the code further comprises instructions for the controller to set the reference uniformity value lower by a selected deviation based on an average value of a plurality of past accumulated reference uniformity values.

9. The system of claim 1, wherein the code further comprises instructions for the controller to group a set of classified battery cells in a descending order according to the uniformity factor.

10. The system of claim 1, wherein the code further comprises instructions for the controller to group a set of classified battery cells having uniformity factors within a same range, and input the group into a battery module assembly process.

11. A battery cell classification method, comprising:
initially charging an assembled battery cell;
determining a charging voltage differential curve during the charging;
extracting a peak value at a state of charge of 60% from the charging voltage differential curve as a uniformity factor;
determining whether the uniformity factor of the battery cell is above a reference uniformity value,
if the uniformity factor is below the reference uniformity value, rejecting the battery cell as a defective battery cell; and
if the uniformity factor at or is above the reference uniformity value, designating the battery cell as a normal battery cell and classifying the battery cell based on the uniformity factor.

12. The method of claim 11, further comprising, after a set quantity of uniformity factors is accumulated from a set of battery cells of a same model, generating a normal distribution of the set of uniformity factors, and setting the reference uniformity value based on the normal distribution.

13. The method of claim 12, wherein the set quantity is set as a quantity of the uniformity factors of battery cells included in one lot or a quantity of the uniformity factors satisfying a normal distribution generation condition.

14. The method of claim 11, wherein the determining the charging voltage differential curve comprises:
deriving a charging voltage curve by using a charging voltage and a charging current measured in time series during charging; and
determining the charging voltage differential curve by first order differentiating the charging voltage curve.

15. The method of claim 11, further comprising:
classifying a set of battery cells based on the uniformity factor of each battery cell of the set of battery cells;
categorizing the set of battery cells based on a ranges of the uniformity factors of the battery cells; and
grouping same categorized battery cells according to a number of battery modules, and inputting the groups into a battery module assembly process.
